(19) United States
(12) Patent Application Publication
(10) Pub. No.: US 2011/0114169 A1
(43) Pub. Date: May 19, 2011

(54) DYE SENSITIZED SOLAR CELLS AND METHODS OF MAKING

(76) Inventors: Curtis Robert Fekety, Corning, NY (US); James Robert Matthews, Painted Post, NY (US); Zhen Song, Painted Post, NY (US)

(21) Appl. No.: 12/943,507

(22) Filed: Nov. 10, 2010

Related U.S. Application Data
(60) Provisional application No. 61/261,937, filed on Nov. 17, 2009.

(51) Int. Cl. H01L 31/0224; H01L 31/18

(52) U.S. Cl. 136/256; 438/98; 257/E31.126

(57) ABSTRACT

Dye sensitized solar cells having conductive metal oxide layers with nano-whiskers and methods of making the dye sensitized solar cells having conductive metal oxide layers with nano-whiskers are described. The method for making a dye sensitized solar cell comprises providing a conductive metal oxide layer comprising nano-whiskers, applying a porous semi-conducting layer on the conductive metal oxide layer, applying a dye to at least a portion of the porous semi-conducting layer, and applying an electrolyte adjacent to at least a portion of the dye.

This application claims the benefit of priority to U.S. Provisional Application 61/261,937 filed Nov. 17, 2009.

### BACKGROUND

1. Field

Embodiments relate to conductive metal oxide films, articles comprising the conductive metal oxide films, and more particularly to dye sensitized solar cells (DSSC) comprising the conductive metal oxide films.

2. Technical Background

Nanowire structures have shown advantages in gas sensing, and in optical and electronic applications. Conventional methods of making nanowire structures include chemical vapor deposition (CVD), atmospheric pressure chemical vapor deposition (APCVD), physical vapor deposition (PVD), sol-gel, hydrothermal and electrochemical deposition methods. These methods can be advantageous in large scale nanowire production or making ordered or aligned nanowire structures.

Transparent and/or electrically conductive film coated glass is useful for a number of applications, for example, in display applications such as the back plane architecture of display devices, for example, liquid crystal displays (LCD), and organic light-emitting diodes (OLED) for cell phones. Transparent and/or electrically conductive film coated glass is also useful for solar cell applications, for example, as an electrode for some types of photovoltaic cells and in many other rapidly growing industries and applications.

Transparent conductive oxides (TCO) are widely used in LCD display panels, Low-E windows, and most recently photovoltaic (PV) cells, E-papers, and in many other industrial applications. Though, cadmium oxide (CdO) is historically the first TCO discovered around 1907, today the most used TCOs are indium tin oxide (ITO) and fluorine doped tin oxide (FTC)) found in the various display panels and the low-E windows, respectively.

TCOs are wide-bandgap semiconductors in nature and typically doped to make them conductors; and are mostly n-type with Fermi-level, ΔE˜kT, right below the conduction band minimum. The first useful p-type TCO (i.e., CuAlO₂) was realized later in 1997 and the field of next-generation “transparent electronics” has since emerged. However, there is a need for high performing TCOs as transparent electrodes in photovoltaics that has drawn much of the attention lately.

Dye sensitized solar cells are a class of solar cells in which a porous support medium (usually a metal oxide, most commonly titania) is “sensitized” with a dye such that when the dye absorbs light, the excited electron is capable of transferring into the conduction band of the support medium. From here the electron must diffuse until it reaches the conductive superstrate (incident to sunlight) and is able to travel round the external circuit. The conductive superstrate should be transparent, in order for light to get to the dye.

There are a number of fundamental issues that affect the efficiency of dye sensitized solar cells. One of the more important issues is that of getting the electrons produced by injection from the dye into the metal oxide to the transparent conducting oxide (TCO) electrode. Once in the metal oxide, the electrons can diffuse in any direction since there is effectively no electric field in this layer. As a result, many electrons encounter traps (often defect sites) in the layer before reaching the electrode. In this way the efficiency of the device is reduced. One way to minimize this is to shorten the path between the point at which each electron is generated and the conductive electrode. However, the challenge is to do this without reducing the actual thickness of the film, because to do so reduces the amount of dye in the path of the light and therefore the number of electrons produced per incident unit of power (light).

It would be advantageous to have a conductive metal oxide useful for TCO applications, for example, in dye sensitized solar cells.

### SUMMARY

Solar cells having conductive metal oxide layers as described herein, address one or more of the above-mentioned disadvantages of conventional solar cells.

One embodiment is a dye sensitized solar cell comprising a conductive metal oxide layer, wherein the conductive metal oxide layer comprises nano-whiskers; a porous semi-conducting layer in contact with the conductive metal oxide layer; a dye in contact with at least a portion of the porous semi-conducting layer; and an electrolyte adjacent to at least a portion of the dye.

Dye sensitized solar cells comprising a conductive metal oxide layer comprising nano-whiskers may address the issue of how to reduce the path length of the electron in the semi-conducting layer without reducing the thickness of the semi-conducting layer.

Another embodiment is a method for making a dye sensitized solar cell, the method comprises:
providing a conductive metal oxide layer comprising nano-whiskers;
applying a porous semi-conducting layer to the conductive metal oxide layer;
applying a dye to at least a portion of the porous semi-conducting layer; and
applying an electrolyte adjacent to at least a portion of the dye.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework to understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawings.

FIG. 1 is an illustration of features of an exemplary DSSC.

FIG. 2 is a scanning electron microscope (SEM) image of an exemplary FTO used in making a DSSC, according to one embodiment.

FIG. 3 is a graph of current versus voltage (I/V) characteristics of an exemplary dye sensitized solar cell with an FTO comprising nano-whiskers and a smooth FTO.

FIG. 4 is a graph comparing I/V characteristics for exemplary dye sensitized solar cells with FTOs (electrodes) comprising nano-whiskers and with different sheet resistances.

### DETAILED DESCRIPTION

Reference will now be made in detail to various embodiments of the invention, an example of which is illustrated in the accompanying drawings.

As used herein, the terms “substrate” and “superstrate” can be used interchangeably to describe either a substrate or a superstrate depending on the configuration of the dye sensitized solar cell. For example, the substrate is a superstrate, if when assembled into a dye sensitized solar cell, it is on the light incident side of a dye sensitized solar cell. The superstrate can provide protection for the materials from impact and environmental degradation while allowing transmission of the appropriate wavelengths of the solar spectrum. Further, multiple dye sensitized solar cells can be arranged into a dye sensitized solar cell module.

As used herein, the term “adjacent” can be defined as being in close proximity. Adjacent structures may or may not be in physical contact with each other. Adjacent structures can have other layers and/or structures disposed between them.

As used herein, the term “planar” can be defined as having a substantially topographically flat surface.

Although exemplary numerical ranges are described in the embodiments, each of the ranges can include any numerical value including decimal places within the range including each of the ranges endpoints.

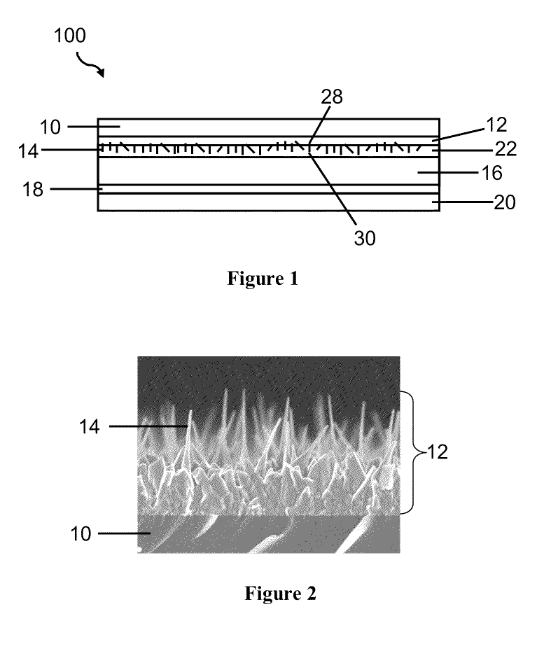

One embodiment is a dye sensitized solar cell, features 100 of which are shown in FIG. 1, comprising a conductive metal oxide layer 12, wherein the conductive metal oxide layer comprises nano-whiskers 14; a porous semi-conducting layer 22 in contact with the conductive metal oxide layer; a dye in contact with at least a portion of the porous semi-conducting layer; and an electrolyte 16 adjacent to at least a portion of the dye.

FIG. 2 is an SEM of an exemplary conductive metal oxide layer 12 comprising nano-whiskers 14. The superstrate 10 in this example is a glass superstrate. In this example, the conductive metal oxide layer is a fluorine doped tin oxide (FTC)).

In one embodiment, the porous semi-conducting layer has a thickness greater than the length of the longest nano-whisker. In this embodiment, the nano-whiskers are covered by the porous semi-conducting layer.

In one embodiment, the conductive metal oxide layer comprises a transparent conductive oxide, Cl doped SnO₂, F and Cl doped SnO₂, F doped SnO₂, Cd doped SnO₂, Sb doped SnO₂, or combinations thereof.

The solar cell, according to one embodiment and shown in FIG. 1, further comprises a superstrate 10 adjacent to the conductive metal oxide layer 12.

In one embodiment and shown in FIG. 1, the solar cell further comprises a counter electrode 18 adjacent to the electrolyte and on an opposite side to the superstrate. The counter electrode can comprise, for example, a platinized conductive layer. In one embodiment, the solar cell further comprises a substrate 20 adjacent to the counter electrode. The substrate can comprise a glass, according to one embodiment.

In one embodiment, the superstrate comprises a glass, a plastic, a non-glassy crystalline solid, or a combination thereof. The superstrate can be transparent. For example, the superstrate comprises a glass layer. In another embodiment, the superstrate is a glass superstrate.

According to one embodiment, the porous semi-conducting layer comprises a metal oxide, titania, zinc oxide or a combination thereof. In one embodiment, the combination of the conductive metal oxide layer and the porous semi-conducting layer is porous.

The electrolyte can be in physical contact with the dye, in one embodiment. The dye, in some embodiments, coats the pores of the porous semi-conducting layer. In one embodiment, the bulk of the dye infiltrates and is contained within the porous semi-conducting layer.

The nano-whiskers, in one embodiment, have an average diameter of from 1 nanometer to 100 nanometers, for example, from 1 nm to 50 nm, for example, from 1 nm to 30 nm, for example 1 nm to 20 nm. In one embodiment, the nano-whiskers have an average diameter of from 10 nm to 30 nm. Each of the nano-whiskers has a distal end 30 projecting away from a corresponding area of attachment 28, in one embodiment which is shown in FIG. 1. The area of attachment can be the superstrate or the conductive metal oxide layer. The nano-whiskers, according to one embodiment, have an average length of from greater than 0 to 1 micron in length. In one embodiment, the nano-whiskers have an average density in the range of from 1 to 10 per micron squared, for example, an average density in the range of from 1 to 5 per micron squared.

The conductive metal oxide layer, in one embodiment, has a thickness of 3 microns or less, for example, 2 microns or less, for example, 1 micron or less, for example, 500 nanometers or less, for example, 100 nanometers or less, for example, 50 nanometers or less. In another embodiment, the film has a thickness in the range of from 10 nanometers to 1000 nanometers, for example, 10 nanometers to 500 nanometers.

In some embodiments, the nano-whiskers of the conductive metal oxide layer penetrate into the porous semi-conducting layer, thus significantly reducing the average distance from any point on the surface of the porous semi-conducting layer (where the electrons are generated) to a point on the surface of the conductive metal oxide layer (electron collector). This reduced distance from the point of electron generation to collection in turn reduces the probability that electrons once produced will be lost in traps and their energy wasted. This reduction in lost electrons translates into an increase in efficiency of the dye sensitized solar cell (DSSC).

Being transparent, the nano-whiskers of the TCO penetrating into the porous semi-conducting layer, for example, titania may act as light conduits to deliver light further through the layers in some embodiments. This may be advantageous in distributing the light more effectively.

Another embodiment is a method for making a dye sensitized solar cell, the method comprises:
providing a conductive metal oxide layer comprising nano-whiskers;
applying a porous semi-conducting layer to the conductive metal oxide layer;
applying a dye to at least a portion of the porous semi-conducting layer; and
applying an electrolyte adjacent to at least a portion of the dye.

Providing the conductive metal oxide layer, in one embodiment comprises forming the conductive metal oxide layer using a hydrolysis reaction.

In one embodiment, providing the conductive metal oxide layer comprises providing a solution comprising a metal oxide precursor, for example, a metal halide, and a solvent, preparing aerosol droplets of the solution, and applying the aerosol droplets to a heated glass superstrate, converting the metal oxide precursor to a metal oxide to form the conductive metal oxide layer, for example, a TCO layer on the glass superstrate.

Hydrolysis reactions are possible when the solvent comprises water. In these reactions, the metal halide reacts with water and converts to its respective oxide. When the solvent comprises only alcohol, a flash reaction can occur in the presence of oxygen where the alcohol is evaporated and/or combusted. The metal halide, for example, tin chloride, reacts with the oxygen to form its respective oxide. In one embodiment, the oxide sinters to form a conductive metal oxide layer. The conductive metal oxide layer is transparent in some embodiments.

According to one embodiment, the solution comprises water. In some embodiments, the solvent in the solution is water.

In one embodiment, when the metal oxide precursor is a tin precursor, the tin precursor is selected from tin chloride (SnCl₂), tin tetrachloride (SnCl₄), and combinations thereof. The tin precursor can be in an amount of from 5 to 35 weight percent, for example from 13 to 25 weight percent or, for example, from 5 to 20 weight percent of the solution, for example, 13 weight percent or more of the solution.

In some embodiments, the solution further comprises a dopant precursor. The dopant precursor can be selected from HF, NH₄F, SbCl₃, and combinations thereof, for example.

According to one embodiment, preparing aerosol droplets comprises atomizing the solution. Atomizing the solution, according to one embodiment, comprises flowing a gas selected from argon, helium, nitrogen, carbon monoxide, or hydrogen in nitrogen and oxygen, through the solution in an atomizer. According to another embodiment, atomizing the solution comprises flowing ambient air through the atomizer. In some embodiments, the velocity of the atomized solution can be between 2 liters per minute (L/min) and 7 L/min, for example, 3 L/min. The velocity, in some embodiments, may depend on the scale of the application. The aerosol droplets, in one embodiment, have median droplet size of less than 1 micron in diameter, for example, a droplet size of from 10 nanometers to 999 nanometers, for example, 50 nanometers to 450 nanometers.

Applying the aerosol droplets, according to one embodiment, comprises spraying the aerosol droplets from one or more sprayers adapted to receive the aerosol droplets from the atomizer and located proximate to the glass substrate.

The aerosol sprayer can be of any shape depending on the shape of the superstrate to be coated and the area of the superstrate to be coated. Spraying the aerosol droplets can comprise translating the sprayer(s) in one or more directions relative to the superstrate, for example, in an X direction, a Y direction, a Z direction or a combination thereof in a three dimensional Cartesian coordinate system.

In one embodiment, applying the aerosol droplets comprises flowing the aerosol droplets into a heating zone, for example, a furnace or a heating plate. The superstrates can be positioned in the heating zone so as to receive the flow of aerosol droplets such that the droplets are deposited onto the superstrate.

In one embodiment, the superstrate is in a form of a glass sheet. In another embodiment, the superstrate is planar and can be used as a superstrate or substrate in a dye sensitized solar cell.

According to one embodiment, the method comprises applying the aerosol droplets to the superstrate that is at a temperature of from 400 degrees Celsius to 530 degrees Celsius. In some applications, the upper end of the temperature range is dependent on the softening point of the glass substrate. The conductive metal oxide layers are typically applied at a temperature below the softening point, for example, of the glass superstrate. According to one embodiment, the conductive metal oxide layer is formed at ambient pressure.

Applying the porous semi-conducting layer, in one embodiment, comprises making a slurry of a metal oxide powder in a solvent such as an alcohol, for example, ethanol and casting the slurry onto the conductive metal oxide layer. In one embodiment, dry aerosol deposition may be used to deposit the slurry.

The method, according to one embodiment, further comprises sintering the porous semi-conducting layer after applying.

Nano-whiskers can be developed on SnO₂ base transparent conductive layers using wet aerosol chemical deposition such as the nano-liquid chemical deposition methods described herein. The nano-whiskers typically appear when the temperature of the deposition is from 400° C. to 530° C. At lower temperatures (below 400° C.), needle structures can be developed with the bottoms of the needles having diameters of from 50 nm to 100 nm and the tips having diameters of 20 nm. Nano-whiskers form at higher deposition temperature (500° C.) with each of the nano-whiskers having an average diameter of from 10 nm to 30 nm, for example, 20 nm.

### EXAMPLES

Samples of fluorine doped tin oxide (FTO) coated glass superstrates were prepared by methods previously described. Of these superstrates, representative samples were chosen having similar sheet resistances but different morphologies in order to compare the effect of nano-whisker vs. smooth TCO electrodes on the performance of a DSSC. The sheet resistance of the two samples chosen for the comparison experiment was −27 Ω/□.

The conditions used to form the FTO coatings lead to the structure of the final conductive metal oxide layers. The density of the nano-whiskers of the FTO, the absolute height and the aspect ratio of the nano-whiskers can all play a role in the efficiency of dye sensitized solar cells made using the conductive metal oxide layers comprising nano-whiskers. For example, it may be advantageous for the nano-whiskers to not exceed the height of the desired porous semi-conducting layer, for example, a porous titania film. It also may be advantageous for the nano-whisker dimensions to not be too large. Being too long may make them stick out above the titania film, which may provide extra opportunity for the system to locally short circuit, and being too wide means they may take up extra volume that could be occupied by dyed titania, thus reducing efficiency (being of diameters or lengths on the order of the light wavelengths could be advantageous). The FTO layer comprising nano-whiskers, in this example, had a nano-whisker density of ˜5×10⁶/mm² or 5/μm². The average nano-whisker length was ˜1 μm.

Dye sensitized solar cells were made using the above described samples using the following procedure: The FTO coated superstrates were cleaned in a plasma cleaner to remove any surface contamination. The cleaned coated superstrates were then placed on a level platform beneath an applicator guide rail that ran beyond the length of the superstrate. Associated samples of glass of the same thickness were placed next to the FTO coated superstrates to extend the usable space for the applicator cube, such that the cube did not start or finish on the FTO coated superstrate. This extended the usable section of titania film produced on the FTO coated superstrate. Titania powder was slurried in ethanol and cast onto the substrates using the applicator cube.

In this example, a Degussa P25 was used as the titania with a 6.7 wt % loading in ethanol for slurry formation. The titania was weighed into the ethanol and shaken thoroughly for 2 min. This suspension was then sonicated for between 10 and 15 min to aid in the dispersion of the titania nanoparticles. The final thickness of the titania film can be determined by the laydown gap height and by the volume fraction of titania in the slurry. With the FTO coated superstrate secured to the level platform with guide rail, the applicator cube was placed on the extra piece of glass in front of the superstrate such that the desired applicator gap (in this case 37 μm) was facing down on the side facing away from the superstrate and toward the user. The applicator cube was filled with the titania slurry to a depth of at least ⅛″ above the glass. Less than a ⅛″ gap will affect the width of the laydown and create a thickness variation from the center to the edge of the film. The applicator cube was pressed lightly down on the glass and against the guide rail.

The applicator cube was steadily pushed forward across the length of the superstrate. This steady motion generated a porous titania layer that, once dried then sintered, was dyed and incorporated into a DSSC. Drying took approximately 15 min in a drying oven at 100° C. The porous semi-conducting layer was then sintered at 450° C. in a furnace. This was achieved by placing the FTO coated superstrates with the titania layer in a furnace at room temperature then ramping the temperature as follows: ramp temperature to 250° C. at a rate of 8° C./min, hold temperature at 250° C. for 30 min, ramp temperature from 250° C. to 450° C. at a rate of 8° C./min, hold temperature at 450° C. for 30 min, ramp temperature from 450° C. to 50° C. at a rate of 8° C./min. The sintered samples were then removed from the furnace and cooled to room temperature.

The sintered porous titania layer was then dyed using Ruthenium 535 (also known as N3), a ruthenium bipyridyl based dye commercially available from Solaronix. The porous titania layers were immersed in a solution of the ruthenium dye (20 mg of dye per 100 mL of anhydrous ethanol) for 20 hours. After 20 hours soaking the samples were removed from the dye solution, rinsed with anhydrous ethanol, and dried with a stream of nitrogen gas.

Once the porous titania layers were dyed, the titania needed to be trimmed down to leave room around the edge of the titania layer for a gasket to be applied. This was done by carefully scraping away the titania with a single edge razor blade. This may be done before dying if so desired, but it is usually more convenient to trim the titania subsequent to dying. Square patches of dyed titania (1 cm×1 cm) were left to act as the active cell area.

The platinum layer, in this example, a platinum film for the back electrode was made in a similar way to the porous titania layer. Pt-catalyst T/SP, Pt paste, available from Solaronix was applied to a sheet of TCO on glass (in this case commercially available FTO coated 1737) in a thin film using the applicator cube with a 50 μm laydown thickness. These films were then heated at 400° C. for 30 min to form the platinum film by removing the other components of the paste.

SX 1170-60 (60 micron thick film (polymer)) from Solaronix was used as the gasket material for assembling the solar cells. The strips of gasket material were cut and placed on the dyed titania samples to fit around the perimeter abutting the titania, leaving two gaps at diagonally opposite corners of the titania patch. This was achieved by cutting four strips of the gasket material. For a 2″×1″ superstrate with a 1 cm×1 cm titania patch, two of the four gasket strips should be 0.3″ wide and 1″ in length, appropriate to reach from one side of the superstrate to the other. The other two should be 0.3″ wide and 0.3″ in length for spanning most of the other two edges, leaving 0.1″ gaps at opposite corners for filling and air escape. The resulting gasket pattern resembled two carpenter squares, each made from two rulers, one ruler being shorter than the other. The angles of these squares enveloped opposite corners of the titania patch, leaving the two other opposite corners open for electrolyte filling.

The counter electrode was placed on top of this gasket, ensuring the platinum coated side faced down toward the gasket and that the platinum completely covered the titania electrode within the gasket just assembled. When assembling the cell it was important to position the two electrodes (titania on superstrate and platinum on substrate) and orient them such that there was sufficient TCO coated substrate freely accessible from each electrode to attach the wires for the external circuit. The newly assembled solar cell was held together using clamps that applied gentle pressure. A combination of Officemate International Corporation, BC-50 and BC-20 binder clips were used to apply the appropriate pressure to secure the solar cell together and allow for heat sealing of the gasket.

These clamped solar cells were heated in a drying oven, or other suitable heat source may be used, at 125° C. for approximately 7 min, until the gasket softened and sealed the two halves of the solar cell together leaving no gaps, except the two deliberately left for electrolyte filling and air escape. Longer heating may cause the gasket material to soften too much and the gap between the two electrodes may become significantly reduced. This gasket softening and sealing may be carried out at temperatures between 100° C. and 125° C., with increased heating time for lower temperatures. Once the gasket has sealed the two electrodes together into a cell, the cell was removed from the oven and allowed to cool to room temperature, at which point the clamps were removed.

Electrolyte used for the final assembly was made using methods know in the art. The cells were filled by drawing electrolyte into the fill space created between the gaskets; the other fill space allowed air to escape as capillary action pulled the electrolyte across the electrode until it reached the fill space. Once all the air was displaced by electrolyte, the solar cells were sealed. This was done using Adhesive Tech High Temp. hot glue. The glue was applied to completely cover both of the fill holes and allowed to set for at least 4 hours.

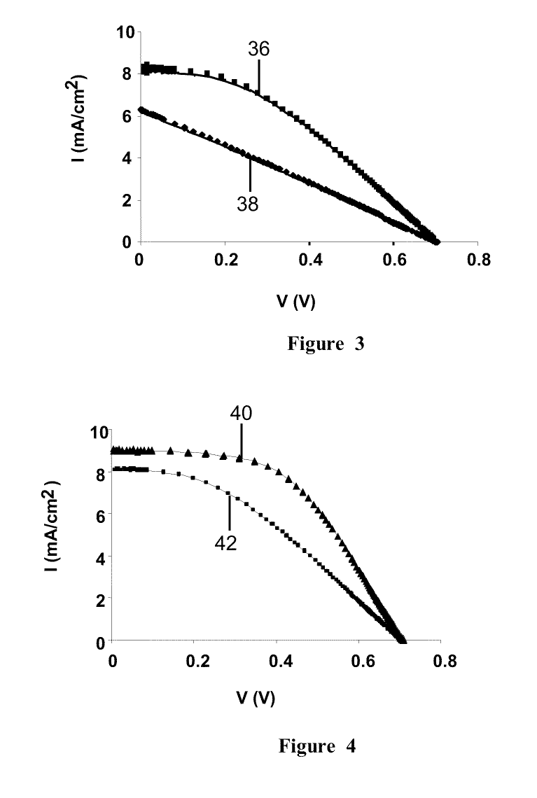

Once assembled, the current versus voltage (I/V) characteristics of the dye sensitized solar cells were measured by varying the resistive load placed in the external circuit and measuring the voltage and current for each load. FIG. 3 shows the resulting I/V characteristics of the solar cells produced using a smooth conductive metal oxide layer, shown by line 38, and a conductive metal oxide layer comprising nano-whiskers, shown by line 36, in this example, both FTO layers with comparable sheet resistances.

FIG. 3 shows that the FTO comprising nano-whiskers produces an efficiency increase over the smooth FTO. The overall performance may be improved by increasing the thickness of the FTO thereby reducing the sheet resistance. In this example, the sheet resistance is higher than would be desired in practice. This partially decreased the cell efficiency. However, further tests with the FTO comprising nano-whiskers based on thicker base layers produced improvement to the cell efficiency as shown in FIG. 4. Line 42 shows the efficiency of a solar cell with the FTO comprising nano-whiskers and having a higher sheet resistance. Line 40 shows the efficiency of a solar cell with the FTO comprising nano-whiskers and having a lower sheet resistance.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A dye sensitized solar cell comprising:
a conductive metal oxide layer, wherein the conductive metal oxide layer comprises nano-whiskers;
a porous semi-conducting layer in contact with the conductive metal oxide layer;
a dye in contact with at least a portion of the porous semi-conducting layer; and
an electrolyte adjacent to at least a portion of the dye.

2. The solar cell according to claim 1, wherein the conductive metal oxide layer comprises a transparent conductive oxide, Cl doped SnO₂, F and Cl doped SnO₂, F doped SnO₂, Cd doped SnO₂, Sb doped SnO₂, or combinations thereof.

3. The solar cell according to claim 1, further comprising a superstrate adjacent to the conductive metal oxide layer.

4. The solar cell according to claim 3, further comprising a counter electrode adjacent to the electrolyte and on an opposite side to the superstrate.

5. The solar cell according to claim 4, wherein the counter electrode comprises a platinized conductive layer.

6. The solar cell according to claim 3, wherein the superstrate comprises a glass, a plastic, a non-glassy crystalline solid, or a combination thereof.

7. The solar cell according to claim 3, wherein the superstrate is transparent.

8. The solar cell according to claim 1, wherein the porous semi-conducting layer comprises a metal oxide, titania, zinc oxide or a combination thereof.

9. The solar cell according to claim 1, wherein the combination of the conductive metal oxide layer and the porous semi-conducting layer is porous.

10. The solar cell according to claim 1, wherein the electrolyte is in physical contact with the dye.

11. The solar cell according to claim 1, wherein the dye coats the pores of the porous semi-conducting layer.

12. The solar cell according to claim 1, wherein the nano-whiskers have an average diameter of from 1 nanometer to 100 nanometers.

13. The solar cell according to claim 1, wherein each of the nano-whiskers has a distal end projecting away from a corresponding area of attachment.

14. The solar cell according to claim 13, wherein the area of attachment is the superstrate or the conductive metal oxide layer.

15. The solar cell according to claim 1, wherein the nano-whiskers have an average length of from greater than 0 to 1 micron in length.

16. The solar cell according to claim 1, wherein the nano-whiskers have an average density in the range of from 1 to 10 per micron squared.

17. A method for making a dye sensitized solar cell, the method comprising:
providing a conductive metal oxide layer comprising nano-whiskers;
applying a porous semi-conducting layer on the conductive metal oxide layer;
applying a dye to at least a portion of the porous semi-conducting layer; and
applying an electrolyte adjacent to at least a portion of the dye.

18. The method according to claim 17, wherein providing the conductive metal oxide layer comprises forming the conductive metal oxide layer using a hydrolysis reaction.

19. The method according to claim 17, wherein applying the porous semi-conducting layer comprises making a slurry of a metal oxide powder in a solvent and casting the slurry onto the conductive metal oxide layer.

20. The method according to claim 19, further comprising sintering the porous semi-conducting layer after applying.
